(19) United States
(12) Patent Application Publication
(10) Pub. No.: US 2019/0148648 A1
(43) Pub. Date: May 16, 2019

(54) ORGANIC LIGHT-EMITTING DIODE AND ORGANIC LIGHT-EMITTING DISPLAY DEVICE INCLUDING THE SAME

(71) Applicant: Samsung Display Co., Ltd., Yongin-si (KR)

(72) Inventors: Changmin LEE, Suwon-si (KR); Jihye SHIM, Namyangju-si (KR); Yeonwoo LEE, Jincheon-gun (KR); Jehong CHOI, Suwon-si (KR); Hyunju CHOI, Seoul (KR); Sangwoo PYO, Seongnam-si (KR); Myungsuk HAN, Suwon-si (KR)

(21) Appl. No.: 16/042,794

(22) Filed: Jul. 23, 2018

(30) Foreign Application Priority Data
Nov. 13, 2017 (KR) 10-2017-0150497

(51) Int. Cl. H01L 51/00; H01L 51/52; H01L 27/32; H01L 51/50

(52) U.S. Cl. CPC H01L 51/0072; H01L 51/5218; H01L 51/5234; H01L 51/5072; H01L 51/5024; H01L 51/0077; H01L 51/5056; H01L 27/3218

(57) ABSTRACT

Disclosed are an organic light-emitting diode and an organic light-emititng display device including the same. The organic light-emitting diode includes: a first electrode; a second electrode disposed opposite to the first electrode; and an organic layer interposed between the first electrode and the second layer and including a hole transport region, a light-emitting layer, an electron transport region, and a diffusion barrier layer, wherein the diffusion barrier layer includes one or more diffusion barrier materials including a 6- to 20-membered N-heterocyclic aromatic compound, a lithium complex, and/or a phosphine oxide-based compound.

### CROSS-REFERENCE TO RELATED APPLICATION

This application claims priority to and the benefit of Korean Patent Application No. 10-2017-0150497, filed on Nov. 13, 2017, in the Korean Intellectual Property Office (KIPO), the entire content of which is incorporated herein by reference.

### BACKGROUND

### 1. Field

Exemplary embodiments of the present disclosure relate to an organic light-emitting diode and an organic light-emitting display device including the same.

### 2. Description of the Related Art

An organic light-emitting display device is a self-luminescent display device that displays images by using organic light-emitting diodes that emit light. This organic light-emitting display device exhibits characteristics, such as low power consumption, high luminance, and high response speed, and is thus currently attracting attention as a display device.

Generally, an organic light-emitting diode includes an anode and a cathode disposed opposite to each other, and an organic layer disposed between the anode and the cathode. Furthermore, the organic layer includes an organic light-emitting layer. Holes supplied from the anode and electrons supplied from the cathode combine to form excitons in the organic light-emitting layer. The organic-light emitting diode emits light by means of energy which is generated when the excitons drop (e.g., transition or relax) to a ground state.

As a method of improving luminance efficiency by effectively extracting the light emitted from the organic light-emitting layer, a microcavity may be used. The microcavity makes use of the principle that light is repeatedly reflected between a reflective layer (e.g., an anode electrode) and a transflective layer (e.g., a cathode electrode) spaced apart from each other by a set or predetermined distance (an optical path length) and, thus, strong interference occurs between the reflected light, so that light having a set or specific wavelength is amplified and light having other wavelengths is cancelled out. Accordingly, the front color reproducibility and luminance of the organic light-emitting display device may be improved.

In order to produce this microcavity effect, the distance between an anode and a cathode in each of red, green, and blue organic-light emitting diodes is determined in accordance with a corresponding one of red, green, and blue wavelengths, and the thickness of an organic layer disposed between the anode and the cathode is also determined in accordance with each of the wavelengths. However, when the organic layer is formed to have a large thickness in order to produce the microcavity effect, the amounts of organic materials used are increased, thereby increasing the manufacturing cost of the organic light-emitting display device.

Therefore, in order to reduce the amounts of organic materials used, research has been conducted to apply an organic layer which is capable of producing the microcavity effect while having a small thickness. However, if the thickness of the organic layer is made smaller, there is an increase in the probability of developing progressive dark spot due to the small thickness of the organic layer, with the result that a problem arises in that the yield of organic light-emitting display devices is reduced.

It is to be understood that while this background section is intended to provide useful background for understanding the subject matter disclosed herein, the background section may include ideas, concepts or recognitions that were not part of what was known or appreciated by those skilled in the pertinent art prior to a corresponding effective filing date of subject matter disclosed herein.

### SUMMARY

Exemplary embodiments of the present disclosure are directed to an organic light-emitting display device including a thin organic layer, which can be manufactured at a low cost and can minimize or reduce the development of dark spots.

According to an exemplary embodiment of the present disclosure, there is provided an organic light-emitting diode including: a first electrode; a second electrode disposed opposite to the first electrode; and an organic layer interposed between the first electrode and the second layer and including a hole transport region, a light-emitting layer, an electron transport region, and a diffusion barrier layer, wherein the diffusion barrier layer includes one or more diffusion barrier materials selected from the group consisting of a 6- to 20-membered N-heterocyclic aromatic compound, a lithium complex and a phosphine oxide-based compound.

According to another exemplary embodiment of the present disclosure, there is provided an organic light-emitting display device including: a substrate; and a plurality of red organic light-emitting diodes, green organic light-emitting diodes, and blue organic light-emitting diodes disposed on the substrate, wherein each of the plurality of red organic light-emitting diodes, green organic light-emitting diodes, and blue organic light-emitting diodes includes: a first electrode disposed on the substrate; a second electrode disposed opposite to the first electrode; and an organic layer interposed between the first electrode and the second layer and including a hole transport region, a light-emitting layer, an electron transport region, and a diffusion barrier layer, and the diffusion barrier layer includes one or more diffusion barrier materials selected from the group consisting of a 6- to 20-membered N-heterocyclic aromatic compound, a lithium complex, and a phosphine oxide-based compound.

The foregoing is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

The above and other features and aspects of embodiments of the present disclosure will be more clearly understood from the following detailed description taken in conjunction with the accompanying drawings, in which:

FIG. 1 is a cross-sectional view schematically illustrating the structure of an organic light-emitting diode according to a first exemplary embodiment of the present disclosure;

FIG. 2 is a cross-sectional view schematically illustrating the structure of an organic light-emitting diode according to a second exemplary embodiment of the present disclosure;

FIG. 3 is a top view of an organic light-emitting display device according to a first exemplary embodiment of the present disclosure;

FIG. 4 is a cross-sectional view taken along line I-I′ of FIG. 3;

FIG. 5 is a schematic view illustrating the organic light-emitting display device of FIG. 4;

FIG. 6 is a schematic view illustrating an organic light-emitting display device according to a second exemplary embodiment of the present disclosure;

FIG. 7 is a schematic view illustrating an organic light-emitting display device according to a third exemplary embodiment of the present disclosure;

FIG. 8 is a schematic view illustrating an organic light-emitting display device according to a fourth exemplary embodiment of the present disclosure;

FIG. 9 is a schematic view illustrating an organic light-emitting display device according to a fifth exemplary embodiment of the present disclosure;

FIG. 10 is a schematic view illustrating an organic light-emitting display device according to a sixth exemplary embodiment of the present disclosure; and

FIGS. 11-14 are TEM images of the organic layers (electron transport layer/diffusion barrier layer) and second electrode portions of samples 1 to 3 and control sample 1, respectively.

### DETAILED DESCRIPTION

Features of embodiments of the present disclosure and methods for achieving them will become apparent from exemplary embodiments described below in more detail in conjunction with the accompanying drawings. However, the present disclosure is not limited to the following exemplary embodiments, but is embodied in various different forms. These exemplary embodiments are provided merely to make the present disclosure complete and fully convey the scope of the subject matter of the present disclosure to a person having ordinary knowledge in the art to which the present disclosure pertains. The subject matter of the present disclosure is defined only by the scope of the attached claims. Therefore, in some exemplary embodiments, well-known process steps, device structures, and technologies are not described in more detail in order to prevent the present disclosure from being obscurely interpreted. Throughout the specification, the same reference symbols refer to the same components.

Unless otherwise defined, all terms used herein (including technical and scientific terms) will have the same meanings as commonly understood by a person having ordinary knowledge in the art to which the present disclosure pertains. Terms, such as those defined in commonly used dictionaries, should not be interpreted in ideal or excessively formal senses unless clearly and particularly defined.

### Organic Light-Emitting Diode

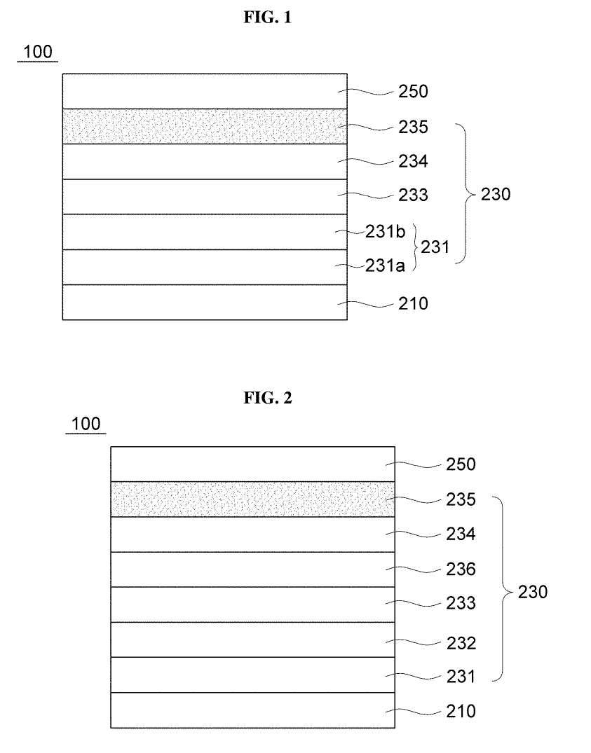

FIG. 1 is a cross-sectional view schematically illustrating the structure of an organic light-emitting diode according to one exemplary embodiment of the present disclosure, and FIG. 2 is a cross-sectional view schematically illustrating the structure of an organic light-emitting diode according to another exemplary embodiment of the present disclosure.

Referring to FIGS. 1-2, an organic light-emitting diode 100 includes: a first electrode 210; a second electrode 250; and an organic layer 230 disposed between the first electrode 210 and the second electrode 250. The organic layer includes a hole transport layer 231, a light-emitting layer 233, an electron transport layer 234, and a diffusion barrier layer 235. Optionally, the organic light-emitting diode 100 may further include one or more selected from the group consisting of: an auxiliary light-emitting layer 232 disposed between the hole transport region 231 and the light-emitting layer 233; a hole-blocking layer 236 disposed between the light-emitting layer 233 and the electron transport region 234; and a capping layer disposed on the second electrode 250.

The individual components of the organic light-emitting diode according to embodiments of the present disclosure will be described in more detail below.

### (1) First Electrode

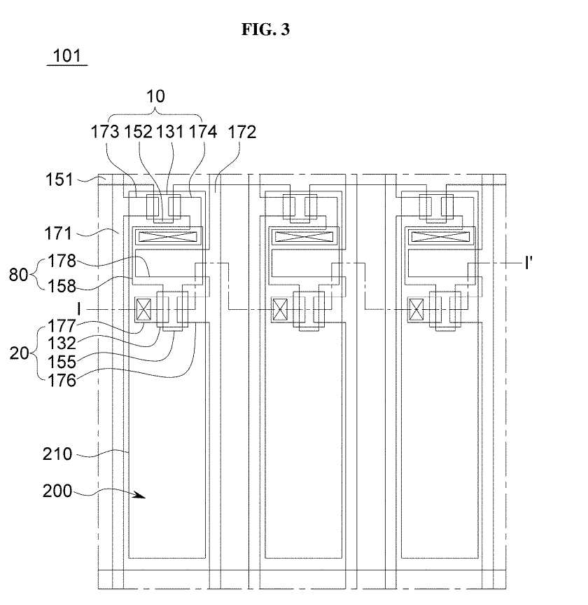

In the organic light-emitting diode 100 according to the present disclosure, the first electrode 210 may be disposed on the substrate 110, and may be electrically coupled to (e.g., electrically connected to) a driving thin-film transistor 20 and receive a driving current from the driving thin-film transistor 20 (see FIG. 3). This first electrode 210 may include a material having a relatively high work function. Accordingly, the first electrode 210 serves as an anode that injects holes into the adjacent hole transport region. In this case, the second electrode 250 disposed opposite to the first electrode 210 serves as a cathode that injects electrons into the adjacent electron transport region 234. However, the first electrode 210 and the second electrode 250 are not limited thereto. In some cases, the first electrode 210 may serve as a cathode, and the second electrode 250 may serve as an anode.

The first electrode 210 may include a metal having high reflectivity. In this case, the first electrode 210 is a reflective electrode, and the organic light-emitting display device may have a top-emission structure. According to one example, the first electrode 210 has a two-layer structure including a reflective layer and a transparent conductive layer disposed on the reflective layer. According to another example, the first electrode 210 has a three-layer structure including a transparent conductive layer (“a first transparent conductive layer”), a reflective layer, and a transparent conductive layer (“a second transparent conductive layer”). In the first electrode 210 having the three-layer structure, the first transparent conductive layer substantially functions as an anode electrode, and the second transparent conductive layer functions to adjust a work function.

The transparent conductive layer may include a transparent material having a relatively high work function, for example, a transparent conductive oxide (TCO). Non-limiting examples thereof include ITO (indium tin oxide), IZO (indium zinc oxide), ZnO (zinc oxide), AZO (aluminum zinc oxide), In₂O₃(indium oxide), SnO₂ (tin oxide), and the like, which may be used alone or as a mixture of two or more thereof. This transparent conductive layer may have a thickness in a range of about 2 to 10 nm, for example, about 5 nm.

The reflective layer include one or more metals selected from among magnesium (Mg), silver (Ag), gold (Au), calcium (Ca), lithium (Li), chromium (Cr), copper (Cu), and aluminum (Al). According to one exemplary embodiment, the reflective layer may be a silver (Ag) or Ag alloy reflective layer. This reflective layer may have a thickness in a range of about 50 to 100 nm.

A method for forming the first electrode 210 is not particularly limited, but the first electrode 210 may be formed using any suitable method used in the art. Examples thereof include, but are not limited to, a sputtering method, a deposition method, and the like.

### (2) Second Electrode

In the organic light-emitting diode 100 according to the present disclosure, the second electrode 250 is disposed opposite to the above-described first electrode 210. For example, the second electrode 250 is disposed on the electron transport region 234. This second electrode 250 may include a material having a relatively low work function. Accordingly, the second electrode 250 serves as a cathode that injects electrons into the adjacent electron transport region.

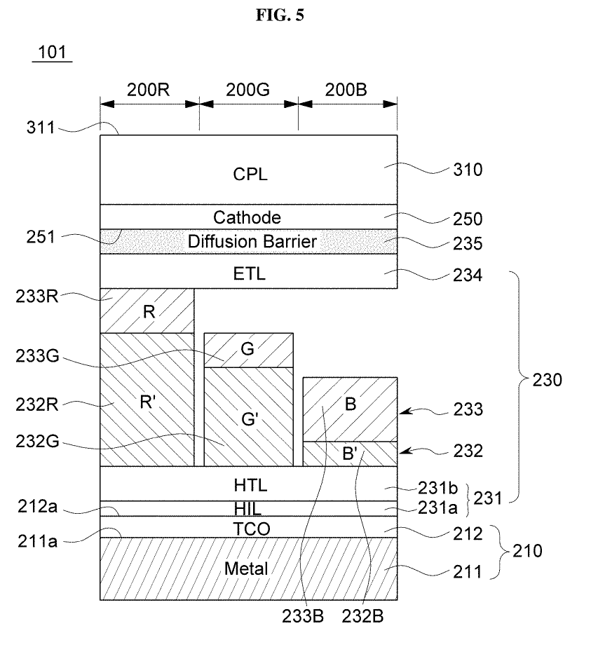

The second electrode 250 may include a silver (Ag)-containing material. In this case, the second electrode 250 may be a transflective or transmissive electrode, and the organic light-emitting display device may have a top-emission structure. In this case, the light emitted from the light-emitting layer 233 may pass through the second electrode 250, and may be also reflected from the bottom 251 of the second electrode 250. Accordingly, the light emitted from the light-emitting layer 233 may be repeatedly reflected between the top 211a of the reflective layer 211 in the first electrode 210 and the bottom 251 of the second electrode 250 (see FIG. 5).

The Ag-containing material includes silver (Ag), a silver-containing alloy, or the like. An example of the silver-containing alloy includes, but is not limited to, an alloy of silver (Ag) and one or more metals (M) selected from the group consisting of magnesium (Mg), lithium (Li), calcium (Ca), chromium (Cr), copper (Cu), aluminum (Al), and ytterbium (Yb).

When the Ag-containing material is an alloy of Ag and M, the mixing ratio between Ag and M may be in a range of from 20:1 to 1:20 (w/w), or, for example, from 10:1 to 1:10 (w/w). When the content of silver in the second electrode is high as described above, the second electrode may have excellent current conductivity, and thus the efficiency of the organic light-emitting diode may be improved.

The second electrode 250 may have a thickness in a range of about 5 to 20 nm. When the thinning and electron supply functions of the diode are considered, the second electrode may have a thickness in a range of about 8 to 15 nm.

A method for forming the second electrode 250 is not particularly limited, but the second electrode may be formed using any suitable method used in the art, like the above-described first electrode. Examples of the method include, but are not limited to, a sputtering method, a deposition method, and the like.

### (3) Organic Layer

In the organic light-emitting diode 100 according to the present disclosure, the organic layer 230 is disposed between the first electrode 210 and the second electrode 250. The organic layer 230 includes a hole transport region 231, a light-emitting layer 233, an electrode transport region 234, and a diffusion barrier layer 235 that are sequentially deposited on the first electrode 210. Optionally, the organic layer 230 may further include at least one layer selected from the group consisting of: an auxiliary light-emitting layer 232 disposed between the hole transport region 231 and the light-emitting layer 233; and a hole-blocking layer 236 disposed between the light-emitting layer 233 and the electron transport region 234.

According to one example, as shown in FIG. 1, the organic light-emitting diode 100 according to the present disclosure may have a structure in which the hole transport region 231, the light-emitting layer 233, the electron transport region 234, and the diffusion barrier layer 235 are sequentially deposited on the first electrode 210.

According to one example, as shown in FIG. 2, the organic light-emitting diode of the present disclosure may have a structure in which the hole transport region 231, the auxiliary light-emitting layer 232, the light-emitting layer 233, the hole-blocking layer 236, the electron transport region 234, and the diffusion barrier layer 235 are sequentially deposited on the first electrode 210.

The individual organic layers will be described in more detail herein below.

### (a) Hole Transport Region

In the organic light-emitting diode 100 of the present disclosure, the hole transport region 231 is a portion of the organic layer 230 disposed on the first electrode 210, and functions to transport holes, injected from the first electrode 210, to another adjacent layer of the organic layer, for example, the light-emitting layer 233. This hole transport region 231 may include one or more selected from the group consisting of a hole injection layer 231a and a hole transport layer 231b. For example, the hole transport region 231 may include a hole injection layer 231a and a hole transport layer 231b that are sequentially deposited on the first electrode 210. In another example, the hole transport region 231 may include only any one selected from the hole injection layer 231a and the hole transport layer 231b.

The hole transport region 231 includes a material having low hole-injection barrier and high hole mobility.

For example, the hole injection layer 231a includes any suitable hole injection material available in the art. Non-limiting examples of the hole injection material include phthalocyanine compounds, such as copper phthalocyanine; DNTPD (N,N′-diphenyl-N,N′-bis[4-(phenyl-m-tolyl-amino)-phenyl]-biphenyl-4,4′-diamine), m-MTDATA (4,4′,4″-tris(3-methylphenylphenylamino)triphenylamine), TDATA (4,4′4″-Tris(N,N-diphenylamino)triphenylamine), 2TNATA (4,4′,4″-tris{N-(2-naphthyl)-N-phenylamino}-triphenylamine), PEDOT/PSS (poly(3,4-ethylenedioxythiophene)/poly(4-styrenesulfonate)), PANI/DBSA (polyaniline/dodecylbenzenesulfonic acid), PANI/CSA (polyaniline/camphor sulfonic acid), PANI/PSS (polyaniline)/poly(4-styrenesulfonate)), and the like, which may be used alone or as a mixture of two or more thereof.

The hole transport layer 231b includes any suitable hole transport material available in the art. Non-limiting examples of the hole transport material include carbazole-based derivatives, such as N-phenylcarbazole, polyvinylcarbazole or the like; fluorine-based derivatives; triphenylamine-based derivatives, such as TPD (N,N′-bis(3-methylphenyl)-N,N′-diphenyl-[1,1-biphenyl]-4,4′-diamine), TCTA (4,4′,4″-tris(N-carbazolyl)triphenylamine) or the like; NPB (N,N′-di(1-naphthyl)-N,N′-diphenylbenzidine), TAPC(4,4′-cyclohexylidene bis[N,N-bis(4-methylphenyl)benzenamine]), and the like, which may be used alone or as a mixture of two or more thereof.

At least one of the hole injection layer 231a and the hole transport layer 231b may further include, in addition to the above-described hole injection material and/or hole transport material, a charge-generating material which is capable of improving the conductivity or the like of the layer. This charge-generating material may be homogeneously or inhomogeneously dispersed in the layer.

Examples of the charge-generating material include a p-dopant, and the like. As the p-dopant, any suitable p-dopant available in the art may be used without limitation. Examples of the p-dopant include, but are not limited to, quinone derivatives, such as tetracyanoquinonedimethane (TCNQ), 2,3,5,6-tetrafluoro-tetracyano-1,4-benzoquinonedimethane (F4TCNQ), and the like, and metal oxides, such as tungsten oxides, molybdenum oxides, and the like. The content of this p-dopant may be suitably or appropriately controlled in a range used in the art, and may range, for example, from about 0.5 to 50 parts by weight based on 100 parts by weight of the hole injection material (and/or the hole transport material).

The hole transport region 231 may be formed using any suitable method used in the art. Examples of the method include, but are not limited to, a vacuum deposition method, a spin coating method, a cast method, a Langmuir-Blodgett (LB) method, an inkjet printing method, a laser printing method, a laser-induced thermal imaging (LITI) method, and the like.

### (b) Light-Emitting Layer

In the organic light-emitting diode 100 of the present disclosure, the light-emitting layer 233 is a portion of the organic layer 230 disposed between the first electrode 210 and the second electrode 250. For example, the light-emitting layer 233 is disposed on the hole transport region 231. This light-emitting layer 233 is a layer in which holes and electrons, injected from the first electrode 210 and the second electrode 250, respectively, combine to form excitons. The color of light emitted from the organic light-emitting diode may differ depending on a material forming the light-emitting layer.

The light-emitting layer 233 may include a host, and may optionally further include a dopant. When the light-emitting layer 233 includes the host and the dopant, the content of the dopant may range from about 0.01 to 25 parts by weight, or, for example, from about 0.01 to 15 parts by weight, based on 100 parts by weight of the host, but is not limited thereto.

The host may be any suitable one available in the art, and is not particularly limited. Examples of the host include, but are not limited to, Alq₃(tris(8-quinolinolato)aluminum), CBP (4,4′-bis(N-carbazolyl)-1,1′-biphenyl), PVK (poly(N-vinylcarbazole), ADN (9,10-di(naphthalene-2-yl)anthracene, TCTA (4,4′,4″-tris(carbazol-9-yl)-triphenylamine, TPBI(1,3,5-tris(N-phenylbenzimidazole-2-yl)benzene, TBADN (3-tert-butyl-9,10-di(naphth-2-yl)anthracene, DSA (distyrylarylene), E3 or CDBP (4,4′-bis(9-carbazolyl)-2,2′-dimethyl-biphenyl), and the like.

The dopant may be any suitable one available in the art, and is not particularly limited. Such dopants may be classified into fluorescent dopants, and phosphorescent dopants. The phosphorescent dopants may be metal complexes including Ir, Pt, Os, Re, Ti, Zr, Hf, or a combination of two or more thereof, but are not limited thereto.

Meanwhile, such dopants may be classified into red dopants, green dopants, and blue dopants. Any suitable red dopants, green dopants, and blue dopants, available in the art, may be used without particular limitation.

For example, non-limiting examples of the red dopant include PtOEP (Pt(II) octaethylporphyrin), Ir(piq)₃ (tris(2-phenylisoquinoline)iridium), Btp₂Ir(acac) (bis(2-(2′-benzothienyl)-pyridinato-N,C3′)iridium(acetylacetonate), and the like, which may be used alone or as a mixture of two or more thereof.

Furthermore, non-limiting examples of the green dopant include Ir(ppy)₃ (tris(2-phenylpyridine)iridium), Ir(ppy)₂(acac) (bis(2-phenylpyridine)(acetylacetonato)iridium(III)), Ir(mppy)₃ (tris(2-(4-tolyl)phenylpiridine)iridium), C545T (10-(2-benzothiazolyl)-1,1,7,7-tetramethyl-2,3,6,7-tetrahydro-1H,5H,11H-[1]benzopyrano[6,7,8-ij]-quinolizin-11-one), and the like, which may be used alone or as a mixture of two or more thereof.

Furthermore, non-limiting examples of the blue dopant include F₂Irpic (bis[3,5-difluoro-2-(2-pyridyl)phenyl](picolinato)iridium(III)), (F₂ppy)₂Ir(tmd), Ir(dfppz)₃, DPVBi (4,4′-bis(2,2′-diphenylethen-1-yl)biphenyl) DPAVBi (4,4′-bis[4-(diphenylamino)styryl]biphenyl), TBPe (2,5,8,11-tetra-tert-butylperylene), and the like, which may be used alone or as a mixture of two or more thereof.

The light-emitting layer 233 may have a single-layer structure including one type (or kind) of material, a single-layer structure including a plurality of different materials, or a multi-layer (at least two-layer) structure formed by depositing two or more different materials to form a plurality of layers. When the light-emitting layer 233 includes a plurality of layers, the organic light-emitting diode may emit light having various suitable colors. For example, when the light-emitting layer 233 includes a plurality of single layers including different materials and arranged in series, the organic light-emitting diode may emit light having mixed colors. Furthermore, when the light-emitting layer includes a plurality of layers, the driving voltage of the diode may increase, but the current value of the organic light-emitting diode may become constant, and thus the organic light-emitting diode may have luminous efficiency that is improved by the number of the light-emitting layers.

This light-emitting layer 233 may be formed using any suitable method used in the art. Examples of the method include, but are not limited to, a vacuum deposition method, a spin coating method, a cast method, a Langmuir-Blodgett (LB) method, an inkjet printing method, a laser printing method, a laser-induced thermal imaging (LITI) method, and the like.

### (c) Electron Transport Region

In the organic light-emitting diode 100 of the present disclosure, the electron transport region 234 is a portion of the organic layer 230 disposed on the light-emitting layer 233, and functions to transport electrons, injected from the second electrode 250, to another adjacent organic layer, for example, the light-emitting layer 233.

This electron transport region 234 may include one or more selected from the group consisting of an electron transport layer 234 and an electron injection layer. As an example, the electron transport region 234 includes the electron transport layer 234. As another example, the electron transport region 234 may include the electron transport layer 234 and an electron injection layer that are sequentially deposited on the light-emitting layer 233.

The electron transport region 234 includes a material into which electrons are easily injected and which has high electron mobility.

For example, the electron transport layer 234 includes any suitable electron transport material available in the art. Non-limiting examples of the electron transport material include oxazole-based compounds, isoxazole-based compounds, triazole-based compounds, isothiazole-based compounds, oxadiazole-based compounds, thiadiazole-based compounds, perylene-based compounds, aluminum complexes (e.g., Alq3 (tris(8-quinolinolato)-aluminum), BAIq, SAIq, and Almq3), gallium complexes (e.g., Gaq'2OPiv, Gaq'2OAc, 2(Gaq'2)), and the like, which may be used alone or a mixture of two or more thereof.

Furthermore, the electron injection layer includes any suitable electron injection material available in the art. Non-limiting examples of the electron injection material include LiF, Li₂O, BaO, NaCl, CsF; lanthanide metals, such as Yb, Sm, La, Ce, Pr, and the like; and metal halides, such as RbCl, Rbl, and the like, which may be used alone or a mixture of two or more thereof.

Furthermore, the electron transport region 234 may include a material having a lowest unoccupied molecular orbital (LUMO) energy level (E₂) which is about 0.1-0.4 eV lower than the LUMO energy level (E₁) of a diffusion barrier material. While the present application is not limited to any particular mechanism or theory, the reason for this is that electrons may be easily injected from the diffusion barrier layer 235 into the electron transport region 234 without increasing the driving voltage of the diode. For example, the electron transport material and/or the electron injection material may be selected by considering the type (or kind) of the diffusion barrier material. Accordingly, the efficiency with which electrons are injected from the diffusion barrier layer into the electron transport region may be improved, and thus the driving voltage and luminous efficiency of the organic light-emitting diode may be improved.

The electron transport region 234 may be formed using any suitable method used in the art. Examples of the method include, but are not limited to, a vacuum deposition method, a spin coating method, a cast method, a Langmuir-Blodgett (LB) method, an inkjet printing method, a laser printing method, a laser-induced thermal imaging (LITI) method, and the like.

### (d) Diffusion Barrier Layer

In the organic light-emitting diode 100 of the present disclosure, the diffusion barrier layer 235 is a portion of the organic layer 230 disposed between the electron transport region 234 and the second electrode 250, and optionally, may be disposed between the electron transport layer 234 and the electron injection layer. The diffusion barrier layer 235 functions to prevent a metal component (for example, silver ion (Ag⁺)) in the second electrode 250 from diffusing and penetrating (or to reduce a likelihood or amount of such penetration) into the electron transport region 234. Furthermore, the diffusion barrier layer 235 may function to planarize the bottom surface of the second electrode 250.

However, the diffusion barrier layer 235 of the present disclosure should not prevent electrons, injected from the second electrode 250, from moving to the electron transport region 234. Accordingly, when the work function of the second electrode material and the LUMO energy level of the electron transport material are considered, the diffusion barrier layer 235 of the present disclosure may include a diffusion barrier material which has excellent electron transport ability and which can prevent the one metal component (for example, silver ion (Ag⁺)) of the second electrode 250 from penetrating (or can reduce a likelihood or amount of such penetration).

Examples of this diffusion barrier material include a 6- to 20-membered N-heterocyclic aromatic compound, a lithium (Li) complex, and a phosphine oxide-based compound, which may be used alone or as a mixture of two or more thereof.

For example, the 6- to 20-membered N-heterocyclic aromatic compound is a 6- to 20-membered aromatic compound including at least one (for example, two or more, or 2 to 3) heterocyclic ring (e.g., pyridine or the like) containing nitrogen (N). N in the N-heterocyclic ring has an unshared electron pair which can bind the metal component (for example, silver ion (Ag⁺)) of the second electrode in the organic light-emitting diode. Accordingly, when the diffusion barrier layer 235 including the 6- to 20-membered N-heterocyclic aromatic compound is applied to the organic light-emitting diode 100, the unshared electron pair of N in the diffusion barrier layer can prevent one metal component (for example, Ag⁺) of the second electrode 250 from diffusing (or can reduce a likelihood or amount of such diffusion) toward the electron transport region 234. This effect of preventing the Ag⁺ from diffusing (or of reducing such diffusion) becomes better as the number of the N-heterocyclic rings increases. Accordingly, the organic light-emitting diode 100 of the present disclosure can prevent a short channel from being formed (or can reduce a likelihood or degree of such a short circuit being formed) between the first electrode 210 and the second electrode 250 due to the diffusion of Ag⁺, and furthermore the development of dark spots in the organic light-emitting display device may be reduced.

Non-limiting examples of this 6- to 20-membered N-heterocyclic aromatic compound include pyridine-based compounds, quinoline-based compounds, phenanthroline-based compounds, and the like, which may be used alone or as a mixture of two or more thereof. For example, the 6- to 20-membered N-heterocyclic aromatic compound may include a phenanthroline-based compound, or the like.

For example, examples of the 6- to 20-membered N-heterocyclic aromatic compound include, but are not limited to, a compound represented by Formula 1 below:

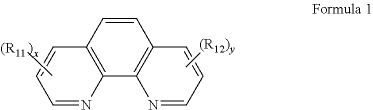

wherein:

R₁₁ and R₁₂ are the same or different, and are each independently selected from the group consisting of a C₁-C₃₀ alkyl group (for example, a C₁-C₁₀ alkyl group) and a C₆-C₃₀ aryl group (for example, a C₆-C₁₀ aryl group); and

x and y are each an integer in a range of 0 to 3.

Examples of the phenanthroline-based compound represented by formula 1 include, but are not limited to, 4,7-diphenyl-1,10-phenanthroline (Bphen), 3,4,7,8-tetramethyl-1,10-phenanthroline (Tmphen), 2,9-dimethyl-4,7-diphenyl-1,10-phenanthroline (BCP), and the like.

The lithium complex is a complex containing lithium (Li) as a central atom, and the lithium in the lithium complex is present as a lithium ion (Li⁺) separated from the ligand in the diffusion barrier layer 235. For example, when the lithium complex is lithium quinolate (Liq), the lithium in the complex is present as Li⁺ separated from the N—O of the ligand. This lithium ion may act as an electrical barrier against one metal component (for example, a silver ion (Ag⁺)) of the second electrode 250 in the organic light-emitting diode. Accordingly, when the diffusion barrier layer 235 including the lithium complex is applied to the organic light-emitting diode, the lithium ion in the diffusion barrier layer 235 can prevent one component (for example, Ag⁺) of the second electrode 250 from diffusing (or can reduce a likelihood or amount of such diffusion) toward the electron transport region 234. Accordingly, the organic light-emitting diode of the present disclosure can prevent a short channel from being formed (or can reduce a likelihood or degree of a short circuit being formed) between the first electrode and the second electrode due to the diffusion of Ag⁺, and furthermore the development of progressive dark spots in the organic light-emitting display device may be reduced.

A lithium complex that may be used in the present disclosure is not particularly limited as long as it is a complex containing lithium (Li) as a central atom. However, when the lithium complex includes a ligand containing a 6- to 20-membered N-heterocyclic ring, the unshared electron pair of N in the ligand can bind Ag⁺, like the above-described 6- to 20-membered N-heterocyclic aromatic compound. Accordingly, the lithium complex may be more effective in preventing or reducing the diffusion of Ag⁺, compared to either a lithium complex not containing the N-heterocyclic ring or LiF. Examples of a lithium complex containing this ligand include, but are not limited to, a lithium complex represented by Formula 2 below:

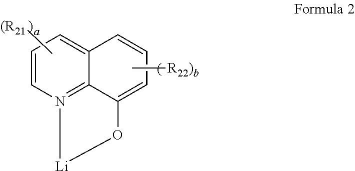

wherein:

R₂₁ and R₂₂ are the same or different, and are each independently selected from the group consisting of a C₁-C₃₀ alkyl group (for example, a C₁-C₁₀ alkyl group) and a C₁-C₃₀ alkyloxy group (for example, a C₁-C₁₀ alkyloxy group); and

a and b are each an integer in a range of 0 to 3.

Examples of the lithium complex represented by formula 2 include, but are not limited to, 8-hydroxyquinolinato lithium (Liq), and the like.

The phosphine oxide-based compound is a compound containing a phosphine oxide group, and can effectively prevent one metal component (for example, Ag⁺) of the second electrode 250 from diffusing (or can reduce a likelihood or amount of such diffusion) without reducing electron movement speed. The p-orbital of oxygen (O) in the phosphine oxide group has an unshared electron pair, and thus the phosphine oxide-based compound has polarity. Accordingly, the diffusion barrier layer 235 including the phosphine oxide-based compound can prevent Ag⁺ from diffusing (or can reduce a likelihood or amount of such diffusion) by binding Ag⁺ to the unshared electron pair of oxygen, like the above-described N-heterocyclic aromatic compound. Accordingly, when the organic light-emitting display device includes the diffusion barrier layer 235 including the phosphine oxide-based compound, the development of progressive dark spots can be reduced.

Examples of this phosphine oxide-based compound include, but are not limited to, a compound represented by Formula 3 below, a compound represented by Formula 4 below, and the like:

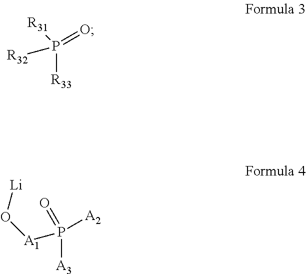

wherein:

R₃₁, R₃₂ and R₃₃ are the same or different and are each independently selected from the group consisting of a C₁-C₃₀ alkyl group, a C₂-C₃₀ alkenyl group, a C₂-C₃₀ alkynyl group, a C₃-C₃₀ cycloalkyl group, a heterocycloalkyl group having 3 to 30 ring-forming atoms (e.g., nuclear atoms), a C₆-C₃₀ aryl group, a heteroaryl group having 5 to 30 ring-forming atoms (e.g., nuclear atoms), a C₁-C₃₀ alkyloxy group, and a C₆-C₃₀ aryloxy group;

A₁ is selected from the group consisting of a C₆-C₃₀ arylene group and a heteroarylene group having 5 to 30 ring-forming atoms (e.g., nuclear atoms);

A₂ and A₃ are the same or different, and are each independently selected from the group consisting of a C₆-C₃₀ aryl group and a heteroaryl group having 5 to 30 ring-forming atoms (e.g., nuclear atoms);

the alkyl, alkenyl, alkynyl, cycloalkyl, heterocycloalkyl, aryl, heteroaryl, alkyloxy, and aryloxy groups of R₃₁, R₃₂ and R₃₃, the arylene and heteroarylene groups of A₁, and the aryl and heteroaryl groups of A₂ and A₃ are each independently unsubstituted or substituted with one or more first substituents selected from the group consisting of a C₁-C₃₀ alkyl group, a C₂-C₃₀ alkenyl group, a C₂-C₃₀ alkynyl group, a C₆-C₃₀ aryl group, a heteroaryl group having 5 to 30 ring-forming atoms (e.g., nuclear atoms), a C₆-C₃₀ aryloxy group, a C₁-C₃₀ alkyloxy group, and a C₆-C₃₀ marylphosphine oxide group, wherein, when the first substituents are plural in number, they may be the same or different; and

the first substituents are each independently unsubstituted or substituted with one or more second substituents selected from the group consisting of a C₁-C₃₀ alkyl group, a C₂-C₃₀ alkenyl group, a C₂-C₃₀ alkynyl group, a C6-C₃₀ aryl group, a heteroaryl group having 5 to 30 ring-forming atoms (e.g., nuclear atoms), a C₆-C₃₀ aryloxy group, a C₁-C₃₀ alkyloxy group, and a C₆-C₃₀ arylphosphine oxide group, wherein, when the second substituents are plural in number, they may be the same or different. In this case, each of the heterocycloalkyl group, the heteroaryl group, and the heteroarylene group contains one or more heteroatoms selected from the group consisting of N, S and O.

Examples of the phosphine oxide-based compound include, but are not limited to, the following compounds:

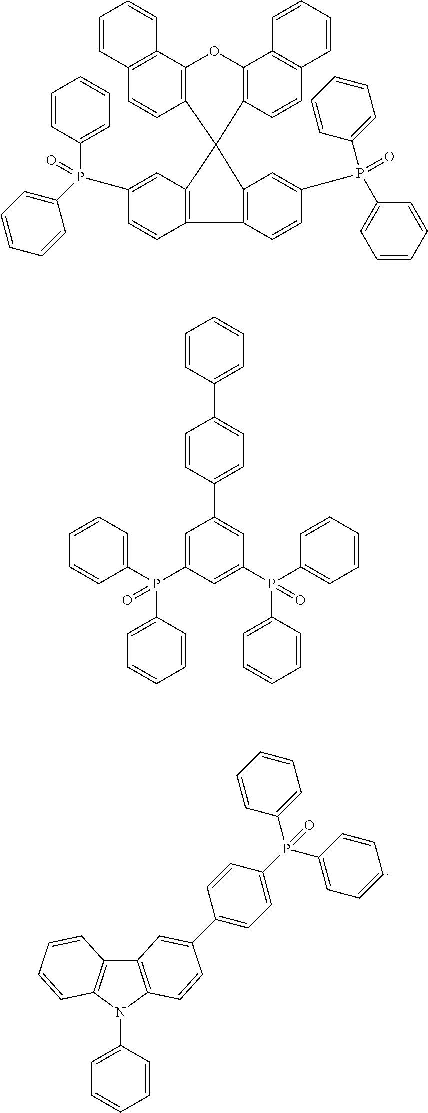 [SMILES: O=P(c1ccccc1)(c1ccccc1)c1ccc2c(c1)C1(c3cc(P(=O)(c4ccccc4)c4ccccc4)ccc3-2)c2ccc3ccccc3c2Oc2c1ccc1ccccc21 ; O=P(c1ccccc1)(c1ccccc1)c1cc(-c2ccc(-c3ccccc3)cc2)cc(P(=O)(c2ccccc2)c2ccccc2)c1 ; O=P(c1ccccc1)(c1ccccc1)c1ccc(-c2ccc3c(c2)c2ccccc2n3-c2ccccc2)cc1]

The diffusion barrier layer 235 may include a diffusion barrier material having an LUMO energy level in a range of about 2.0 eV to 3.5 eV, among the above-described 6- to 20-membered N-heterocyclic aromatic compound, the lithium complex, and the phosphine oxide-based compound. This diffusion barrier layer 235 may prevent one metal component (for example, silver ion (Ag⁺)) of the second electrode 250 from penetrating (or may reduce a likelihood or amount of such penetration) while smoothly injecting electrons, injected from the second electrode 250, toward the electron transport region 234 without increasing the driving voltage of the diode. Accordingly, the driving voltage and luminous efficiency of the organic light-emitting diode of the present disclosure may be improved.

The thickness of the diffusion barrier layer is suitably or appropriately controlled by considering the type (or kind) and content of diffusion barrier material, the content of Ag-containing material in the second electrode, and the like. For example, the thickness of the diffusion barrier layer may be made thicker as the content of Ag-containing material in the second electrode increases. However, in order for the organic light-emitting diode to have a first resonance structure, the diffusion barrier layer may be designed to have a thickness in a range of about 1 to 10 nm. In this case, the thickness ratio between the diffusion barrier layer and the second electrode in a range of from 1: 1.5 to 10, or, for example, 1: 2 to 8. When the thickness ratio between the diffusion barrier layer and the second electrode is within the above-described range, the maximum diffusion depth of Ag⁺ originating from the second electrode may be about 20 nm or less, and the reduction ratio of the maximum diffusion depth (D₂) in the organic light-emitting diode of the present disclosure relative to the maximum diffusion depth (D₁) of Ag⁺ in a comparative organic light-emitting diode not including the diffusion barrier layer,

$$( \frac{{D}_{1} - {D}_{2}}{{D}_{1}} \times 100 ) ,$$

may be reduced to the range of about 20% to 100%. For example, when the diffusion barrier material is a phenanthrone-based compound or a phosphine oxide-based compound, the maximum diffusion depth of Ag⁺ may be about 1 nm or less, or, for example, about 0 nm. Accordingly, according to the present disclosure, Ag⁺ diffused from the second electrode can no longer penetrate into other organic layers (e.g., the electron transport region, etc.) due to the diffusion barrier layer, and thus the development of progressive dark spots in the diode can be reduced.

The above-described diffusion barrier layer 235 may be either a single layer including one type (or kind) of material or a single layer including a mixture of two different materials. Furthermore, the diffusion barrier layer 235 may include a plurality of layers formed by depositing two or more different materials to form respective layers. For example, the diffusion barrier layer 235 may be a single layer including at least one of the lithium complex, the 6- to 20-membered N-heterocyclic aromatic compound, and the phosphine oxide-based compound, or the diffusion barrier layer 235 may have a structure in which at least two of a first diffusion barrier layer including the lithium complex, a second diffusion barrier layer including the 6- to 20-membered N-heterocyclic aromatic compound, and a third diffusion barrier layer including the phosphine oxide-based compound are stacked on each other.

The diffusion barrier layer 235 may be formed using any suitable method used in the art. Examples of the method include, but are not limited to, a vacuum deposition method, a spin coating method, a cast method, a Langmuir-Blodgett (LB) method, an inkjet printing method, a laser printing method, a laser-induced thermal imaging (LITI) method, and the like.

### (e) Auxiliary Light-Emitting Layer

Optionally, the organic light-emitting diode 100 of the present disclosure may further include an auxiliary light-emitting layer 232 disposed between the hole transport region 231 and the light-emitting layer 233 (see FIG. 2). The auxiliary light-emitting layer 232 functions to transport holes, moved from the hole transport region 231, to the light-emitting layer 233, and also functions to control the thickness of the organic layer 230.

This auxiliary light-emitting layer 232 may include a hole transport material which may be the same (e.g., substantially the same) material as the hole transport region 231. Furthermore, the auxiliary light-emitting layers 232 of red, green and blue organic light-emitting diodes may include the same (e.g., substantially the same) material.

Examples of the material of the auxiliary light-emitting layer 232, which are available in the present disclosure, include, but are not limited to, NPD (N,N-dinaphthyl-N,N′-diphenylbenzidine), TPD (N,N′-bis-(3-methylphenyl)-N,N′-bis(phenyl)-benzidine), s-TAD, MTDATA (4,4′,4″-tris(N-3-methylphenyl-N-phenyl-amino)-triphenylamine), and the like, which may be used alone or as a mixture of two or more thereof. Furthermore, the auxiliary light-emitting layer may include a p-type dopant in addition to the above-described material. As the p-type dopant, any suitable p-type dopant available in the art may be used. In this case, the content of the p-type dopant may be suitably or appropriately controlled within any suitable range used in the art, and may range, for example, from about 0.5 to 50 parts by weight based on 100 parts by weight of the hole transport material.

### (f) Hole-Blocking Layer

Optionally, the organic light-emitting diode 100 of the present disclosure may further include a hole-blocking layer 236 disposed between the electron transport region 234 and the light-emitting layer 233 (see FIG. 2). When the light-emitting layer 233 includes a phosphorescent dopant, the hole-blocking layer 236 can prevent triplet excitons or holes from diffusing (or can reduce a likelihood or amount of such diffusion) toward the electron transport region 234.

The hole-blocking layer 236 may include an oxadiazole derivative, a triazole derivative, a phenanthroline derivative (e.g., BCP), or the like.

The thickness of this hole-blocking layer 236 is not particularly limited, and may be controlled within the range in which the driving voltage does not increase substantially. For example, the thickness may range from about 5 to 10 nm.

The hole-blocking layer 236 may be formed using any suitable method used in the art. Examples of the method include, but are not limited to, a vacuum deposition method, a spin coating method, a cast method, a Langmuir-Blodgett (LB) method, an inkjet printing method, a laser printing method, a laser-induced thermal imaging (LITI) method, and the like.

### (4) Capping Layer

Optionally, the organic light-emitting diode 100 of the present disclosure may further include a capping layer 310 disposed on the second electrode 250 (see FIGS. 5-10). The capping layer 310 functions to protect the organic light-emitting diode, and also functions to help the light, emitted from the organic layer, to be efficiently emitted to the outside. For example, the capping layer 310 can prevent light from being lost in the second electrode (or reduce a likelihood or amount of such light loss) due to the total reflection of light in the top-emission organic light-emitting diode.

The capping layer 310 may include at least one selected from the group consisting of tris-8-hydroxyquinolinealuminum (Alq3), ZnSe, 2,5-bis(6′-(2′,2″-bipyridyl))-1,1-dimethyl-3,4-diphenylsilole, 4′-bis[N-(1-naphthyl)-N-phenyl-amino]biphenyl (60 -NPD), N,N′-diphenyl-NN-bis(3-methylphenyl)-1,1′-biphenyl-4,4′-diamine (TPD), and 1,1′-bis(di-4-tolylaminophenyl)cyclohexane (TAPC). The material forming this capping layer 310 is inexpensive compared to the materials of other organic layers of the organic light-emitting diode. Accordingly, resonance may be produced between the top of the first electrode 210 and the top of the capping layer by adjusting the thickness of the capping layer 310 including an inexpensive material instead of reducing the use of expensive organic materials by reducing the distance between the first electrode 210 and the second electrode 250.

Although this capping layer 310 may also be a single layer, it may include two or more layers having different refractive indices so that the reflective index can change gradually while passing through the two or more layers.

The capping layer 310 may be formed using various suitable methods, such as a vacuum deposition method, a spin coating method, a cast method, an LB method, or the like.

The organic light-emitting diode 100 of the present disclosure, which includes the above-described components, may be fabricated according to any suitable method available in the art. For example, the organic light-emitting diode may be fabricated by vacuum-depositing the first electrode material on a substrate and then sequentially vacuum-depositing the hole transport layer material, the light-emitting layer material, the electron transport layer material, the diffusion barrier layer material, and the second electrode material on the first electrode.

### Organic Light-Emitting Display Device

Another exemplary embodiment of the present disclosure is directed to a display device such as, for example, an organic light-emitting display device, which includes the above-described organic light-emitting diode.

FIG. 3 is a top view illustrating an organic light-emitting diode according to one exemplary embodiment of the present disclosure.

Referring to FIG. 3, the organic light-emitting display device of the present disclosure includes a plurality of pixel regions defined by gate lines 151 arranged in one direction, data lines 171 crossing the gate lines 151 in an insulation fashion, and common power supply lines 171. In this case, one pixel is disposed in each of the pixel regions. However, the pixel regions are not limited thereto. Alternatively, the pixel regions may be defined by a pixel-defining layer as described below, and a plurality of pixels may be disposed in each of the pixel regions.

In the organic light-emitting display device of the present disclosure, each pixel has a 2TFT-1CAP structure including: two thin-film transistors (TFTs) including a switching thin-film transistor 10 and a driving thin-film transistor 20; and one capacitor (CAP) 80. However, the pixel is not limited thereto, and may include three or more thin-film transistors and two or more capacitors.

The switching thin-film transistor 10 selects a pixel from which light is to be emitted. This switching thin-film transistor 10 includes: a switching gate electrode 152 coupled to (e.g., connected to) the gate line 151; a source electrode 173 coupled to (e.g., connected to) the data line 171; a switching drain electrode 174 coupled to (e.g., connected to) any capacitor plate of the capacitor 80; and a switching semiconductor layer 131.

The driving thin-film transistor 20 applies a driving voltage to the first electrode 210, which is a pixel electrode of the organic light-emitting diode 200, in order to emit light from the light-emitting layer 233 of the organic light-emitting diode 200 in the pixel selected by the switching thin-film transistor 10. This driving thin-film transistor 20 includes: a gate electrode 155 coupled to (e.g., connected to) a first capacitor plate 158; a driving source electrode 176 coupled to (e.g., connected to) a common power supply line 171; a driving drain electrode 177 coupled to (e.g., connected to) the first electrode 210 of the organic light-emitting diode through a contact hole; and a driving semiconductor layer 132.

The capacitor 80 includes a first capacitor plate 158, a second capacitor plate 178, and an interlayer insulating layer 145 interposed between the first capacitor plate and the second capacitor plate. The first capacitor plate 158 is disposed and coupled between (e.g., connected between) the switching drain electrode 174 and the driving gate electrode 155, and the second capacitor plate 178 is coupled to (e.g., connected to) the common power supply line 172. Furthermore, the interlayer insulating layer 145 serves as a dielectric. The capacitance of the capacitor 80 is determined by the charge stored in the capacitor 80 and the voltage applied between the two capacitor plates 158 and 178.

In the structure of this organic light-emitting display device, the switching thin-film transistor 10 is configured to be operated by a gate voltage applied to the gate line 151 so as to transfer a data voltage, applied to the data line 171, to the driving thin-film transistor 20. In this case, the capacitor 80 stores a voltage corresponding to the difference between a data voltage, transferred through the switching thin-film transistor 10, and a common voltage applied from the common power supply line 172 to the driving thin-film transistor 20, and a current corresponding to the voltage stored in the capacitor 80 flows through the driving thin-film transistor 20 to the light-emitting layer 233 of the organic light-emitting diode 200, with the result that the light-emitting layer 233 emits light.

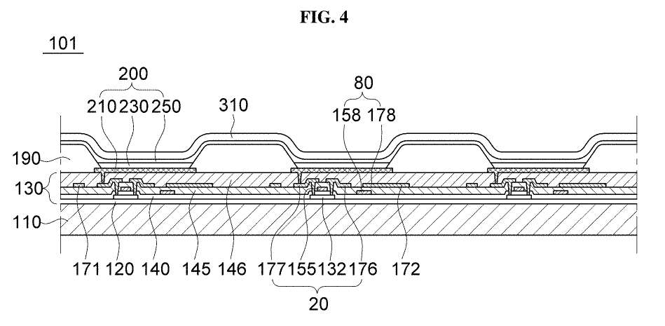

FIG. 4 is a cross-sectional view taken along line I-I′ of FIG. 3, which illustrates one exemplary embodiment of the present disclosure.

Referring to FIG. 4, an organic light-emitting display device according to the exemplary embodiment of the present disclosure includes a substrate 110, a circuit driving unit 130, and an organic light-emitting diode 200.

In the organic light-emitting display device of the present disclosure, the substrate 110 may include an insulating material selected from the group consisting of glass, quartz, ceramic and plastic. However, the substrate 110 is not limited thereto, but may include a metallic material, such as stainless steel.

On this substrate 110, a buffer layer 120 may be further disposed. The buffer layer 120 may include one or more layers selected from among various suitable inorganic and organic layers. This buffer layer 120 functions to prevent impurity elements, such as oxygen, or unnecessary components, such as water, from penetrating (or to reduce a likelihood or amount of such penetration) into the driving circuit unit 130 or the organic light-emitting diode 200, and also functions to planarize the surface of the substrate 110. However, the buffer layer 120 is not essential, but may be omitted.

Furthermore, a gate insulating layer 140 may further be disposed between the gate electrode 152 or 155 and the semiconductor layer 131 or 132 on the substrate 110, and an interlayer insulating layer 145 may further be disposed between the first capacitor plate 158 and the second capacitor plate 178.

Furthermore, a planarizing layer 146 may be further disposed on the interlayer insulating layer 145. The planarizing layer 146 may include an insulating material, and functions to protect the driving circuit unit 130. The planarizing layer 146 may include the same (e.g., substantially the same) material as the above-described interlayer insulating layer 145.

In the organic light-emitting display device of the present disclosure, the driving circuit unit 130 is disposed on the substrate 110 (or the buffer layer 120). The driving circuit unit 130 includes the switching thin-film transistor 10, the driving thin-film transistor 20, and the capacitor 80, and drives the organic light-emitting diode 200.

In the organic light-emitting display device of the present disclosure, the organic light-emitting diode 200 is configured to display an image by emitting light in response to a driving signal received from the driving circuit unit 130. As shown in FIG. 3, the organic light-emitting diode 200 includes a first electrode 210, an organic layer, and a second electrode 250, which are sequentially deposited over the substrate 110.

Since the first electrode 210 and the second electrode 250 are the same as described above in conjunction with the organic light-emitting diode, redundant descriptions thereof are not provided here.

The organic layer 230 includes a hole transport region 231, a light-emitting layer 233, an electron transport region 234, and a diffusion barrier layer 235. Optionally, the organic layer 230 may further include an auxiliary light-emitting layer 232 disposed between the hole transport region 231 and the light-emitting layer 233, and/or a capping layer 310 disposed on the second electrode 250.

As shown in FIGS. 5-10, the hole transport region 231 may include a hole injection layer 231a and a hole transport layer 231b. The hole transport region 231 may include any one selected from the hole injection layer 231a and the hole transport layer 231b. Furthermore, the electron transport region 234 may only the electron transport layer 234 (see FIGS. 5-10), may further include an electron injection layer disposed between the electron transport layer 234 and the second electrode 250, or may include only the electron injection layer instead of the electron transport layer 234. Furthermore, since the individual components of the organic light-emitting display device are the same as described above in conjunction with the organic light-emitting diode, detailed descriptions thereof are omitted.

In the organic light-emitting display device of the present disclosure, the pixel-defining layer 190 serves to define pixel regions, and has openings. The opening of the pixel-defining layer 190 exposes a portion of the first electrode 210. In the opening of the pixel-defining layer 190, the first electrode 210, the organic layer 230, and the second electrode 250 are sequentially deposited. In this case, a portion of the second electrode 250 and a portion of the organic layer 230 may be disposed to overlap each other on the pixel-defining layer 190. Furthermore, at least a portion of the organic layer 230 may be disposed on the pixel-defining layer 190.

In the organic light-emitting display device of the present disclosure, a thin film encapsulating layer may be further disposed on the capping layer 310 in order to protect the organic light-emitting diode 200. The thin film encapsulating layer has a structure in which at least one organic layer and at least one inorganic layer are alternately disposed. This thin film encapsulating layer may prevent water or external gas, such as oxygen, from penetrating (or may reduce a likelihood or amount of such penetration) into the organic light-emitting diode 200.

Furthermore, in the organic light-emitting display device of the present disclosure, an encapsulating substrate may be disposed over the second electrode to be spaced apart from the second electrode 250. The encapsulating substrate may include a transparent material, such as quartz, glass, ceramic or plastic. This encapsulating substrate is bonded to and sealed along with the substrate 110, and covers the organic light-emitting diode 200.

Meanwhile, the organic light-emitting diode 200 and the organic light-emitting display device 101 have a multilayer stack structure, and a significant portion of the light emitted from the organic light-emitting layer 233 cannot pass through this multilayer stack structure and, thus, cannot be emitted to the outside. For this reason, loss of light is caused in the organic light-emitting display device.

In order to allow the light emitted from the light-emitting layer 233 to be effectively emitted to the outside, a microcavity structure is applied to the organic light-emitting diode 200. When light is repeatedly reflected between the first electrode 210 including the reflective layer 211 and the second electrode 250 being a transflective layer, light having a set or specific wavelength corresponding to the reflection distance may be amplified, and light having other wavelengths may be cancelled out. The amplified light may be emitted to the outside through the second electrode 250 which is a transfiective layer.

Accordingly, current organic light-emitting display devices, for example, top-emission active-matrix organic light emitting diode (AMOLED) organic light-emitting display devices, employ second resonance structures having thicknesses of about 2700 Å, 2300 Å and 1800 Å for red, green and blue organic light-emitting diodes, respectively, in order to improve luminous efficiency. However, if the organic layer is made thicker in order to form a microcavity, the amount of organic materials used will increase, thereby increasing the manufacturing cost of the organic light-emitting display device. For this reason, an attempt is made to reduce the thickness of the organic layer. However, when the metal component (for example, Ag⁺) of the second electrode penetrates into the organic layer having a small thickness, the metal component can easily reach the first electrode, and thus the probability of developing progressive dark spots will increase. For this reason, according to the present disclosure, by introducing the organic light-emitting diode including the diffusion barrier layer as described above, the thickness of the first resonance structure (in which the thickness of the organic layer is small) thinner than the structure of the second resonance structure is applied, and thus the diffusion of the second electrode component into the organic layer can be blocked, thereby minimizing or reducing the probability of developing progressive dark spots.

In this case, each layer of the organic light-emitting diode should have a thickness equal to or larger than the minimum layer thickness such that it can perform its function. Accordingly, in the present disclosure, when the minimum layer thickness and the efficiency of thin-layer processes, together with luminous efficiency, are considered, each layer of the organic light-emitting diode is designed such that the first resonance occurs between the first electrode 210 and the second electrode 250, or, for example, between the reflective layer 211 of the first electrode 210 and the second electrode 250.

FIG. 5 is a schematic view illustrating the organic light-emitting display device 101 of FIG. 4. Referring to FIG. 5, the organic light-emitting display device 101 according to the first exemplary embodiment of the present disclosure has a structure in which the first resonance of each of red, green and blue lights occurs between the first electrode 210 and second electrode 250 of each of a red organic light-emitting diode 200R, a green organic light-emitting diode 200G, and a blue organic light-emitting diode 200B.

For this purpose, the organic layer 230 disposed between the first electrode 210 and second electrode 250 of the red organic light-emitting diode 200R according to the first exemplary embodiment of the present disclosure may have a thickness-of about 100 to 120 nm, for example, about 110 nm. Furthermore, the organic layer 230 disposed between the first electrode and second electrode of the green organic light-emitting diode 200G may have a thickness of about 80 to 100 nm, for example, about 90 nm. Furthermore, the organic layer 230 disposed between the first electrode and second electrode of the blue organic light-emitting diode 200B may have a thickness of about 60 to 70 nm, for example, about 65 nm. In this case, the thickness of the diffusion barrier layer 235 of the organic layer 230 is controlled in proportion to the thickness of the second electrode, and may range, for example, from about 1 to 10 nm.

For example, the light-emitting layer 233R of the red organic light-emitting diode 200R has a thickness of about 10 to 40 nm. When the red light-emitting layer 233R has a thickness of about 10 to 40 nm, light may be emitted from the red light-emitting layer 233R. Furthermore, the auxiliary light-emitting layer 232R of the red organic light-emitting diode 200R may have a thickness of about 5 to 40 nm, or, for example, about 10 to 35 nm. In this case, when the thickness of another layer of the organic layer 230 changes, the thickness of the auxiliary light-emitting layer 232R may change also. Accordingly, the auxiliary light-emitting layer 232, 232R, 232G or 232B may function to transport holes to the organic light-emitting diode 233, and may also function to adjust the thickness of the organic layer 230.

Furthermore, the light-emitting layer 233G of the green organic light-emitting diode 200G may have a thickness of about 10 to 40 nm, or, for example, about 20 to 30 nm. Furthermore, the auxiliary light-emitting layer 232G may have a thickness of about 10 to 25 nm, or, for example, about 18 to 22 nm.

Furthermore, the light-emitting layer 233B of the blue organic light-emitting diode 200B may have a thickness of about 10 to 20 nm, or, for example, about 12 to 15 nm. Furthermore, the auxiliary light-emitting layer 232B may have a thickness of about 0 to 5 nm, or, for example, about 3 to 5 nm.

Furthermore, each of a hole injection layer 231a, a hole transport layer 231b, an electron transport region 234 and a diffusion barrier layer 235 is deposited to be shared by the red, green and blue organic light-emitting diodes 200R, 200G and 200B. The hole injection layer 231a may have a thickness of about 5 to 10 nm. The hole transport layer 231b may have a thickness of about 5 to 20 nm. The electron transport region 234 may have a thickness of about 20 to 40 nm. Furthermore, the diffusion barrier layer 235 may have a thickness of about 1 to 10 nm, or, for example, about 1 to 5 nm.

Furthermore, in order to achieve the resonance between the bottom 211a of the reflective layer 211 of the first electrode 210 and the top 311 of the capping layer 310, the thickness of the capping layer 310 may be controlled. For example, the capping layer 310 of the organic light-emitting display device 102 according to the first exemplary embodiment of the present disclosure may have a thickness of 60 to 100 nm, for example, about 80 nm.

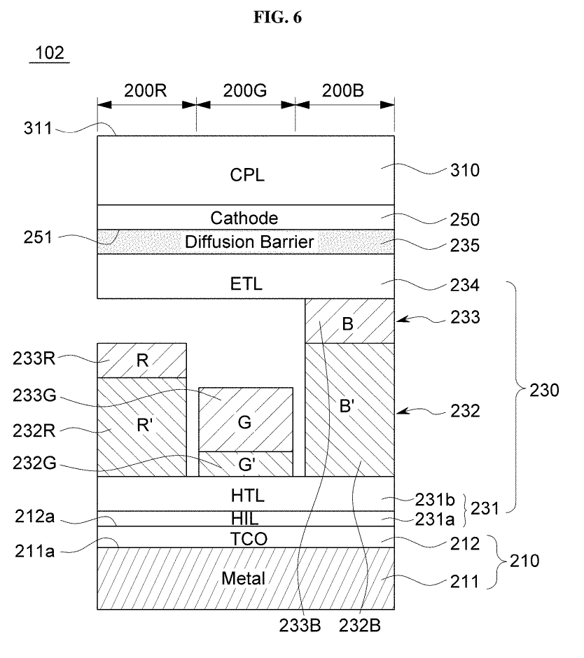

A second exemplary embodiment of the present disclosure will be described below with reference to FIG. 6.

FIG. 6 is a schematic view illustrating an organic light-emitting display device 102 according to the second exemplary embodiment of the present disclosure. The descriptions of the components described in conjunction with the first exemplary embodiment will not be provided here in order to avoid redundant descriptions.

Unlike red and green organic light-emitting diodes, blue organic light-emitting diodes having the first resonance thickness reduce the efficiency thereof compared to those having the second resonance structure when the blue organic light-emitting diodes have the first resonance thickness. For this reason, in the second exemplary embodiment of the present disclosure, the first resonance structure is applied to the red and green light-emitting diodes, and the second resonance structure is applied to the blue light-emitting diode.

The organic light-emitting display device 102 according to the second exemplary embodiment of the present disclosure has the first resonance structure in which red and green lights resonate primarily in the red organic light-emitting diode 200R and the green organic light-emitting diode 200G, respectively, and also has the second resonance structure in which blue light resonates secondarily in the blue organic light-emitting diode 200B.

For this purpose, the organic layer 230 of the red organic light-emitting diode 200R according to the second exemplary embodiment of the present disclosure may have a thickness of about 100 to 120 nm, for example, about 110 nm. Furthermore, the organic layer 230 of the green organic light-emitting diode 200G may have a thickness of about 80 to 100 nm, for example, about 90 nm. Furthermore, the organic layer 230 of the blue organic light-emitting diode 200B may have a thickness of about 175 to 195 nm, for example, about 180 nm. In this case, the thickness of the diffusion barrier layer 235 of the organic layer 230 is controlled in proportion to the thickness of the second electrode.

For example, the light-emitting layer 233R of the red organic light-emitting diode 200R may have a thickness of about 10 to 40 nm, for example, about 35 nm. Furthermore, the auxiliary light-emitting layer 232R of the red organic light-emitting diode 200R may have a thickness of about 5 to 40 nm, or, for example, about 10 to 35 nm.

Furthermore, the light-emitting layer 233G of the green organic light-emitting diode 200G may have a thickness of about 10 to 40 nm, or, for example, about 20 to 30 nm. Furthermore, the auxiliary light-emitting diode 232G may have a thickness of about 10 to 25 nm, or, for example, about 10 nm.

Furthermore, the light-emitting layer 233B of the blue organic light-emitting diode 200B may have a thickness of about 10 to 20 nm, or, for example, about 12 to 15 nm. Furthermore, the auxiliary light-emitting layer 232B may have a thickness of about 80 to 120 nm, or, for example, about 90 to 100 nm.

Each of a hole injection layer 231a, a hole transport layer 231b, an electron transport region 234, and a diffusion barrier layer 235 is deposited to be shared by the red, green and blue organic light-emitting diodes 200R, 200G and 200B. The hole injection layer 231a may have a thickness of about 5 to 10 nm. The hole transport layer 231b may have a thickness of about 5 to 40 nm. Furthermore, the electron transport region 234 may have a thickness of about 20 to 40 nm. Furthermore, the diffusion barrier layer 235 may have a thickness of about 1 to 10 nm, or, for example, about 1 to 5 nm.

Furthermore, the capping layer 310 of the organic light-emitting display device 102 according to the second exemplary embodiment of the present disclosure may have a thickness of about 60 to 100 nm, for example, 80 nm.

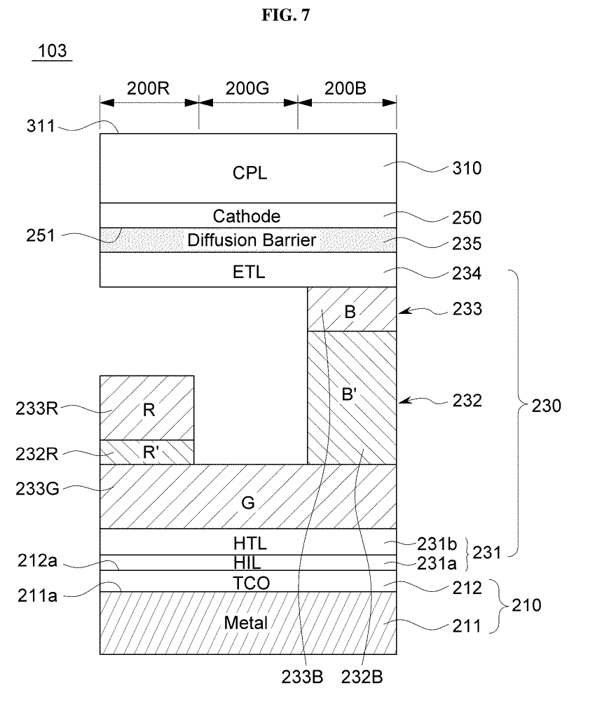

A third exemplary embodiment of the present disclosure will be described below with reference to FIG. 7. FIG. 7 is a schematic view illustrating an organic light-emitting display device 103 according to the third exemplary embodiment of the present disclosure.

The organic light-emitting display device 103 according to the second exemplary embodiment has the first resonance structure in which red and green lights resonate in a red organic light-emitting diode 200R and a green organic light-emitting diode 200G, respectively, and also has the second resonance structure in which blue light resonates in a blue organic light-emitting diode 200B. In this case, the green organic light-emitting diode 200G is used as a green common layer (GCL). The green organic light-emitting diode 200G that is used as the common layer may be disposed at the bottom of each of the red organic light-emitting diode 200R and the blue organic light-emitting diode 200B.

The thickness of each of the red organic light-emitting diode 200R, green organic light-emitting diode 200G and blue organic light-emitting diode 200B in the third exemplary embodiment of the present disclosure is the same as that in the above-described second exemplary embodiment.

For example, the light-emitting layer 233R of the green organic light-emitting diode 200G that is used as the common layer may have a thickness of about 10 to 40 nm, or, for example, about 20 nm.

Furthermore, the light-emitting layer 233R of the red organic light-emitting diode 200R may have a thickness of about 10 to 40 nm, for example, about 15 nm. Furthermore, the auxiliary light-emitting layer 232R in the red organic light-emitting diode 200R may have a thickness of about 5 to 40 nm, or, for example, about 10 to 35 nm.

Furthermore, the light-emitting layer 233B of the blue organic light-emitting diode 200B may have a thickness of about 10 to 20 nm, or, for example, about 12 to 15 nm. Furthermore, the auxiliary light-emitting layer 232B may have a thickness of about 60 to 100 nm, or, for example, about 70 to 80 nm.

Each of a hole injection layer 231a, a hole transport layer 231b, an electron transport region 234, and a diffusion barrier layer 235 is deposited to be shared by the red, green and blue organic light-emitting diodes 200R, 200G and 200B. Since the thicknesses of the hole injection layer 231a, the hole transport layer 231b, the electron transport region 234, the diffusion barrier layer 235, and the capping layer 310 are the same as described above in conjunction with the second exemplary embodiment, redundant descriptions thereof are not provided here.

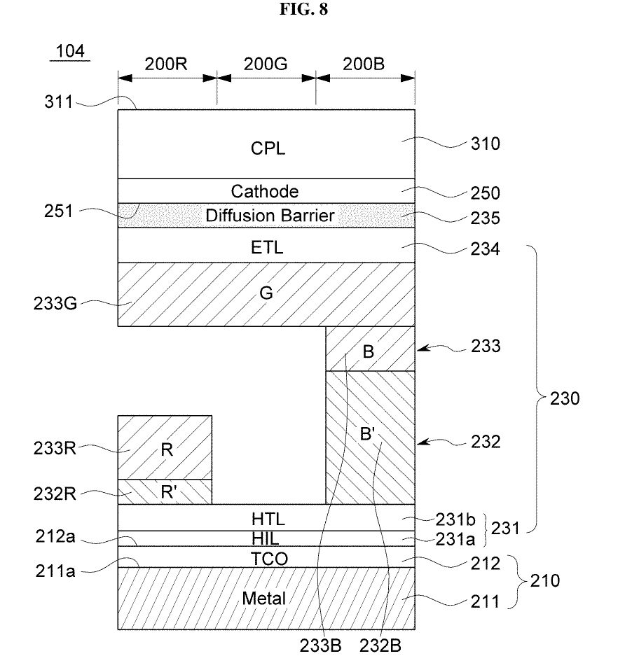

FIG. 8 is a schematic view illustrating an organic light-emitting display device 104 according to a fourth exemplary embodiment of the present disclosure.

The organic light-emitting display device 104 according to the fourth exemplary embodiment of the present disclosure has the first resonance structure in which red and green lights resonate primarily in the red organic light-emitting diode 200R and the green organic light-emitting diode 200G, respectively, and also has the second resonance structure in which blue light resonates secondarily in the blue organic light-emitting diode 200B. In this case, the green organic light-emitting diode 200G is used as a green common layer (GCL). The green organic light-emitting diode 200G that is used as the green common layer may be disposed on the top of each of the red organic light-emitting diode 200R and the blue organic light-emitting diode 200B.

Since the thickness of the organic layer 230 in each of the red organic light-emitting diode 200R, green organic light-emitting diode 200G and blue organic light-emitting diode 200B according to the fourth exemplary embodiment of the present disclosure, and the thicknesses of the light-emitting layer 233R, 233G or 233B, auxiliary light-emitting layer 232R or 232B, hole injection layer 231a, hole transport layer 231b, electron transport region 234 and diffusion barrier layer 235 of the organic layer, and the thickness of the capping layer 310 are the same as described above in conjunction with the third embodiment, redundant descriptions thereof are not provided here.

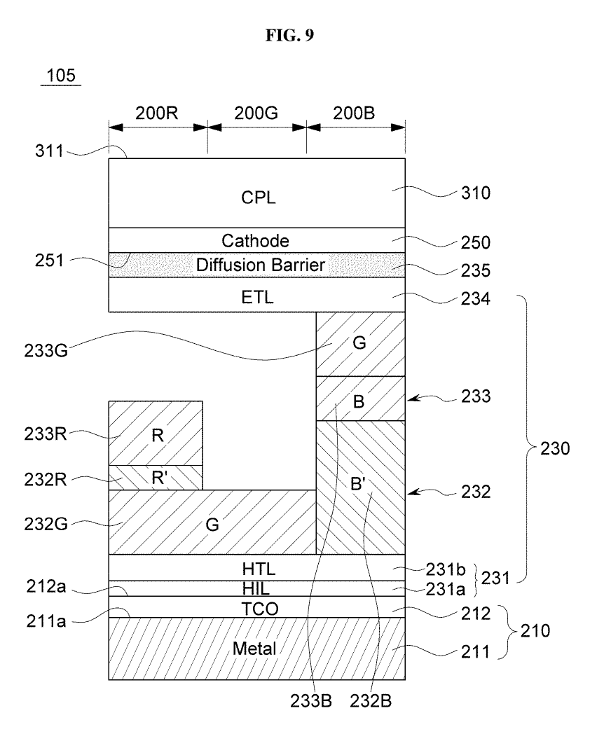

FIG. 9 is a schematic view illustrating an organic light-emitting display device 105 according to a fifth exemplary embodiment of the present disclosure.

The organic light-emitting display device 105 according to the fifth exemplary embodiment of the present disclosure has the first resonance structure in which red and green lights resonate primarily in the red organic light-emitting diode 200R and the green organic light-emitting diode 200G, respectively, and also has the second resonance structure in which blue light resonates secondarily in the blue organic light-emitting diode 2006. In this case, the green organic light-emitting diode 200G is used as a green common layer (GCL). The green organic light-emitting diode 200G that is used as the green common layer is a hybrid structure which is disposed on each of the bottom of the red organic light-emitting diode and the top of the blue organic light-emitting diode.

Since the thickness of the organic layer 230 in each of the red organic light-emitting diode 200R, green organic light-emitting diode 200G and blue organic light-emitting diode 2006 according to the fifth exemplary embodiment of the present disclosure, and the thicknesses of the light-emitting layer 233R, 233G or 233B, auxiliary light-emitting layer 232R or 232B, hole injection layer 231a, hole transport layer 231b, electron transport region 234 and diffusion barrier layer 235 of the organic layer, and the thickness of the capping layer 310 are the same as described above in conjunction with the third embodiment, redundant descriptions thereof are not provided here.

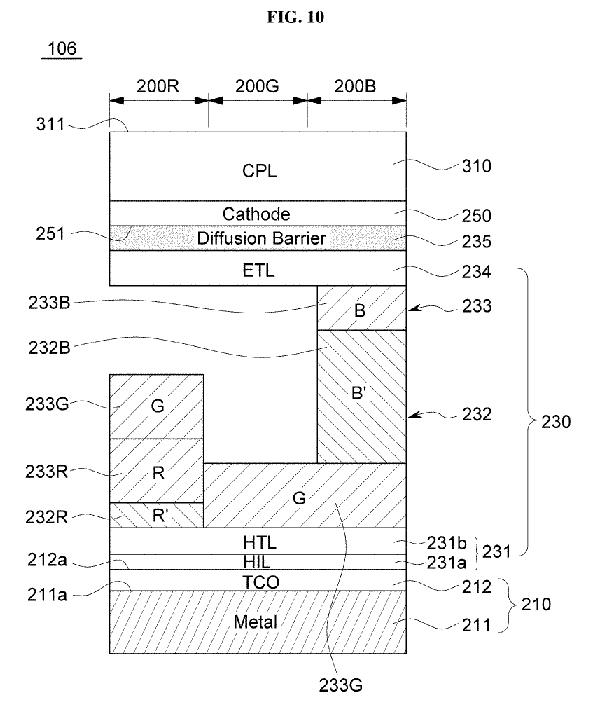

FIG. 10 is a schematic view illustrating an organic light-emitting display device 106 according to a sixth exemplary embodiment of the present disclosure.

The organic light-emitting display device 106 according to the fifth exemplary embodiment of the present disclosure has the first resonance structure in which red and green lights resonate primarily in the red organic light-emitting diode 200R and the green organic light-emitting diode 200G, respectively, and also has the second resonance structure in which blue light resonates secondarily in the blue organic light-emitting diode 2008. In this case, the green organic light-emitting diode 200G is used as a green common layer (GCL). The green organic light-emitting diode 200G that is used as the green common layer is a hybrid structure which is disposed on each of the top of the red organic light-emitting diode and the bottom of the blue organic light-emitting diode.

Since the thickness of the organic layer 230 in each of the red organic light-emitting diode 200R, the green organic light-emitting diode 200G, and the blue organic light-emitting diode 200B according to the sixth exemplary embodiment of the present disclosure, and the thicknesses of the light-emitting layer 233R, 233G or 233B, auxiliary light-emitting layer 232R or 232B, hole injection layer 231a, hole transport layer 231b, electron transport region 234, and diffusion barrier layer 235 of the organic layer, and the thickness of the capping layer 310 are the same as described above in conjunction with the third embodiment, redundant descriptions thereof are not provided here.

The above-described organic light-emitting display devices include an organic layer having a small thickness that makes the first resonance structure possible, and thus these display devices have the effects of reducing material cost and minimizing or reducing the development of dark spots. Accordingly, these display devices have excellent luminous efficiency, and may be applied to flexible organic light-emitting display devices that have recently attracted a lot of attention in the display field, as well as lighting devices.

The subject matter of the present disclosure will be described in further detail below with reference to examples. However, these examples are intended to illustrate embodiments of the present disclosure, and the scope of the present disclosure is not limited to these examples.

### EXAMPLE 1

On a 5.1″-sized ITO/Ag/ITO substrate (panel) having full high definition (FHD) resolution, the following compounds a and p were co-deposited to form a hole injection layer having a thickness of 5 nm. Then, the following compound a was deposited on the hole injection layer to form a hole transport layer having a thickness of 30 nm. On the hole transport layer, CBP and Ir(ppy)₃ were co-deposited at a weight ratio of 100:6 to form a green light-emitting layer having a thickness of 15 nm. On the green light-emitting layer, the following compound γ was deposited to form an electron transport layer having a thickness of 35 nm, and, on the electron transport layer, Liq as a diffusion barrier material was deposited to a thickness of 3 nm. On the diffusion barrier layer, ytterbium (Yb) as an electron injection layer material was deposited to form an electron injection layer having a thickness of 5 nm, and, on the electrode injection later, a silver magnesium alloy (AgMg) was deposited to form a counter electrode having a thickness of 13 nm. On the counter electrode, an optical auxiliary layer having a thickness of 90 nm was vacuum-deposited, thereby fabricating a top-emission green organic light-emitting diode having the first resonance structure and also fabricating an organic light-emitting display device including the same. In this Example, the fabrication of the organic light-emitting display device was performed inside a high-vacuum chamber with a vacuum level of 1×10⁻⁷ Torr.

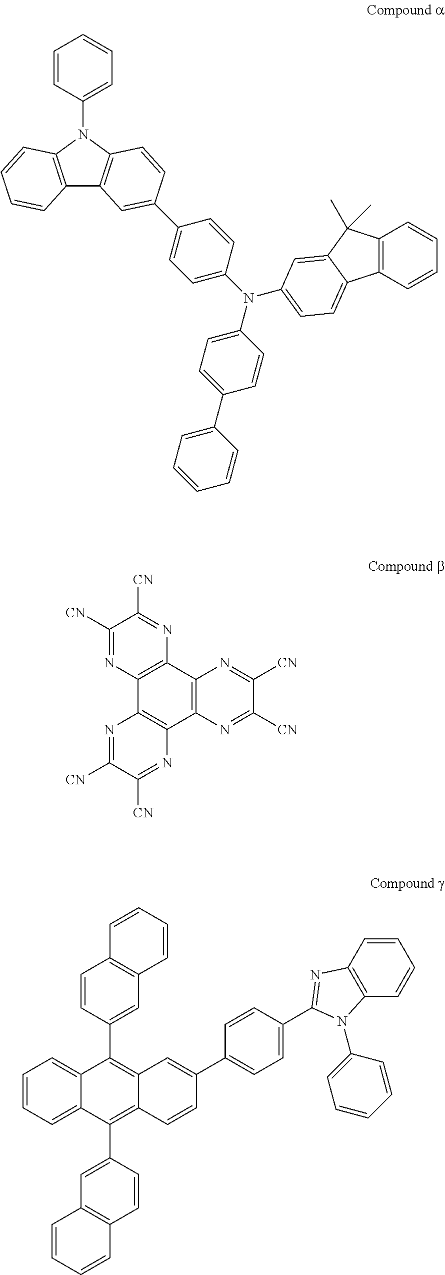

### EXAMPLE 2

An organic light-emitting display device was fabricated in substantially the same manner as described in Example 1, except that Bphen (4,7-diphenyl-1,10-phenanthroline) was used instead of Liq as the diffusion barrier material.

### EXAMPLE 3

An organic light-emitting display device was fabricated in substantially the same manner as described in Example 1, except that the following compound A was used instead of Liq as the diffusion barrier material.

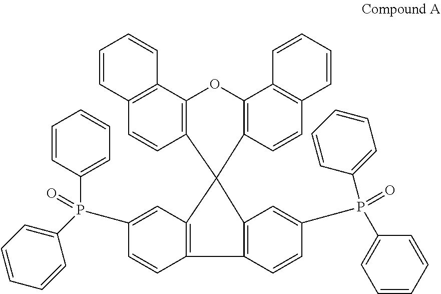 [SMILES: O=P(c1ccccc1)(c1ccccc1)c1ccc2c(c1)C1(c3cc(P(=O)(c4ccccc4)c4ccccc4)ccc3-2)c2ccc3ccccc3c2Oc2c1ccc1ccccc21]

### COMPARATIVE EXAMPLE 1

An organic light-emitting display device was fabricated in substantially the same manner as described in Example 1, except that the diffusion barrier layer was not formed.

### TEST EXAMPLE 1

### Evaluation of Ag⁺ Diffusion-Blocking Ability of Diffusion Barrier Layer

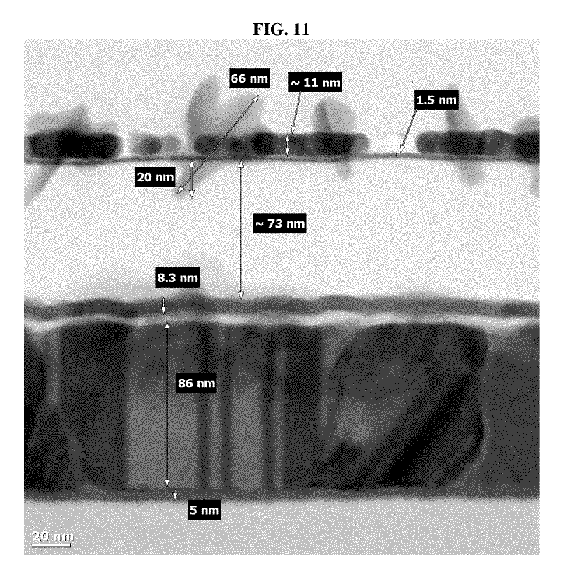

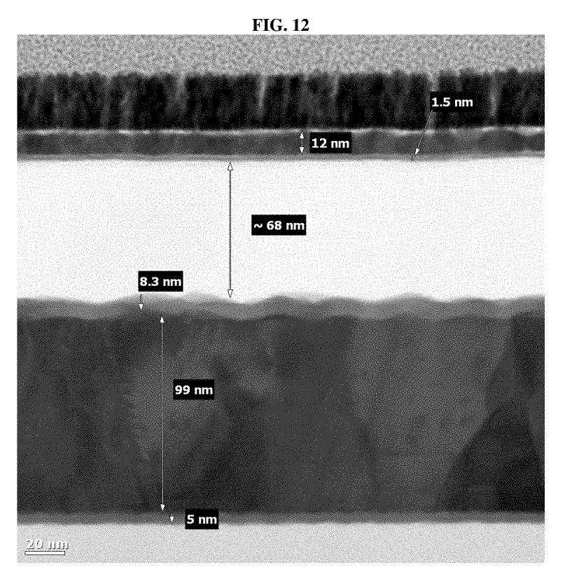

Whether the second electrode component would diffuse in the organic light-emitting display device was evaluated, and the results of the evaluation are shown in FIGS. 11-14.

First, sample 1 composed of a 300 Å thick electron transport layer (Alq3), a 30 Å thick diffusion barrier layer (Liq), and a 130 Å thick second electrode (Ag: Mg alloy, 10:1 w/w) was prepared, and then a cross-section of sample 1 was observed using a transmission electron microscope (TEM). Furthermore, as sample 2, one prepared using Bphen instead of the diffusion barrier material Liq of sample 1 was used, and, as sample 3, one prepared using compound A (see Example 3) instead of the diffusion barrier material Liq of sample 1 was used. As control sample 1, one prepared by excluding the diffusion barrier layer from sample 1 was used.

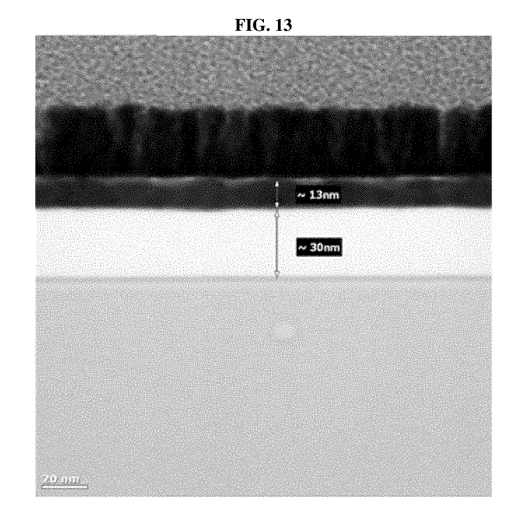

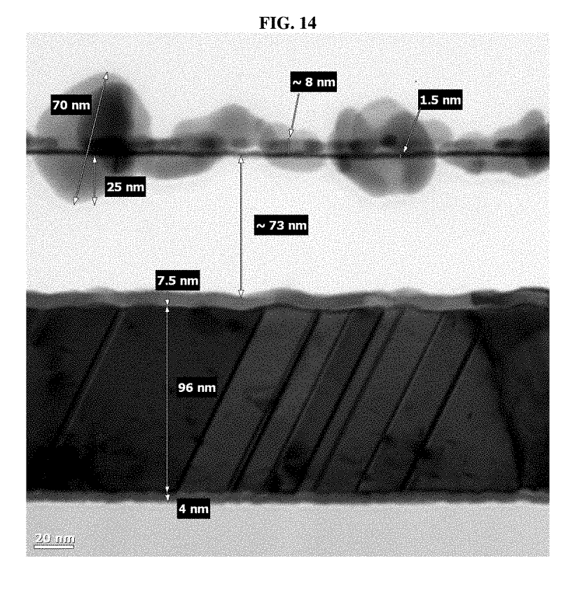

The test results indicated that the penetration depth of the second electrode component in the organic light-emitting display device of Comparative Example 1 was a maximum of 25 nm (see FIG. 14). However, as can be seen in FIGS. 11-13, the penetration depth of the second electrode component in the organic light-emitting display devices of Examples 1 to 3 decreased significantly compared to that in the organic light-emitting display device of Comparative Example 1. For example, it could be seen that, in the case of the organic light-emitting display devices of Examples 2 and 3, the second electrode component hardly penetrated into the organic layer (see FIGS. 12-13).

### TEST EXAMPLE 2

### Evaluation of Development of Dark Spots in Organic Light-Emitting Display Devices

Using the organic light-emitting display devices fabricated in Examples 1 to 3 and Comparative Example, the development of dark spots per cell of the diode of each of the display devices was measured.

For example, the cross-section of each of the organic light-emitting display devices was imaged by an SEM, and the number of dark spots in each cell (5.1″ size and FHD resolution) of the green light-emitting diode was measured as a first-resonance basis. The results of the measurement are shown in Table 1 below:

TABLE 1

| | Number of dark spots | | | | | |
|---|---|---|---|---|---|---|
| | Cell 1 | Cell 2 | Cell 3 | Cell 4 | Cell 5 | Average |
| Example 1 | 2 | — | 6 | 10 | — | 6.0 |
| Example 2 | 4 | 6 | 10 | 6 | 1 | 5.4 |
| Example 3 | 9 | 3 | 7 | 0 | 2 | 4.2 |
| Comparative | 12 | 29 | 22 | 14 | 11 | 17.6 |
| Example 1 | | | | | | |

Referring to Table 1 above, it can be seen that the development of dark spots in the organic light-emitting display devices of Examples 1 to 3 including the diffusion barrier layer was significantly decreased by about 70% compared to that in the organic light-emitting display device of Comparative Example 1.

As described above, the organic light-emitting display device according to the exemplary embodiment of the present disclosure includes an organic layer having a small thickness. Accordingly, the organic light-emitting display device can be manufactured at a low cost.

Furthermore, in the organic light-emitting display device according to the exemplary embodiment of the present disclosure, the development of dark spots of metal ion attributable to the small thickness of the organic layer can be minimized or reduced.

Moreover, the organic light-emitting display device according to the exemplary embodiment of the present disclosure makes it possible to reduce the thickness of materials used for each pixel, thereby increasing yield per time and also increasing the continuous operation time of a production line for display devices.

Unless otherwise noted, like reference numerals denote like elements throughout the attached drawings and the written description, and thus, descriptions thereof will not be repeated. In the drawings, the relative sizes of elements, layers, and regions may be exaggerated for clarity.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

It will be understood that when an element or layer is referred to as being “on,” “connected to,” or “coupled to” another element or layer, it can be directly on, connected to, or coupled to the other element or layer, or one or more intervening elements or layers may be present. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments only and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” and “including,” when used in this specification, specify the presence of the stated features, integers, acts, operations, elements, and/or components, but do not preclude the presence or addition of one or more other features, integers, acts, operations, elements, components, and/or groups thereof. As used herein, the term “and/or” includes any and all combinations of one or more of the associated listed items. Expressions such as “at least one of,” when preceding a list of elements, modify the entire list of elements and do not modify the individual elements of the list.

As used herein, the terms “substantially,” “about,” and similar terms are used as terms of approximation and not as terms of degree, and are intended to account for the inherent deviations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively. Also, the term “exemplary” is intended to refer to an example or illustration.

Also, any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

While the exemplary embodiments of the present disclosure have been described with reference to the accompanying drawings, it will be appreciated by a person having ordinary knowledge in the art to which the present disclosure pertains that the present disclosure may be practiced in other specific forms without changing the technical spirit and essential feature of the present disclosure. Therefore, it should be understood that the above-described embodiments are illustrative from all aspects and are not limitative.

What is claimed is:

1. An organic light-emitting diode comprising:
a first electrode;
a second electrode disposed opposite to the first electrode; and
an organic layer interposed between the first electrode and the second layer, and comprising a hole transport region, a light-emitting layer, an electron transport region, and a diffusion barrier layer,
wherein the diffusion barrier layer comprises one or more diffusion barrier materials selected from the group consisting of a 6- to 20-membered N-heterocyclic aromatic compound, a lithium complex, and a phosphine oxide-based compound.

2. The organic light-emitting diode of claim 1, wherein the 6- to 20-membered N-heterocyclic aromatic compound comprises a compound represented by Formula 1 below: 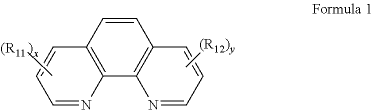
wherein:
R₁₁ and R₁₂ are identical or different, and are each independently selected from the group consisting of a C₁-C₃₀ alkyl group and a C₆-C₃₀ aryl group; and
x and y are each an integer in a range of 0 to 3.

3. The organic light-emitting diode of claim 1, wherein the lithium complex comprises a ligand containing a 6- to 20-membered N-heterocyclic ring.

4. The organic light-emitting diode of claim 3, wherein the lithium complex is represented by Formula 2 below: 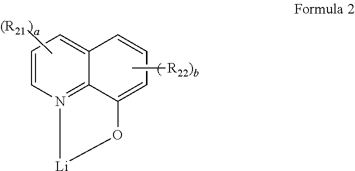
wherein:
R₂₁ and R₂₂ are identical or different, and are each independently selected from the group consisting of a C₁-C₃₀ alkyl group and a C₁-C₃₀ alkyloxy group; and
a and b are each an integer in a range of 0 to 3.

5. The organic light-emitting diode of claim 1, wherein the phosphine oxide-based compound is represented by Formula 3 or 4 below: 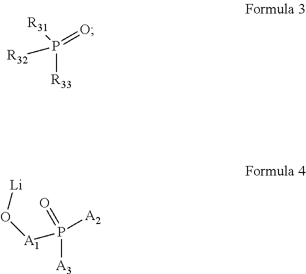
wherein:
R₃₁, R₃₂ and R₃₃ are identical or different, and are each independently selected from the group consisting of a C₁-C₃₀ alkyl group, a C₂-C₃₀ alkenyl group, a C₂-C₃₀ alkynyl group, a C₃-C₃₀ cycloalkyl group, a heterocycloalkyl group having 3 to 30 ring-forming forming atoms, a C6-C₃₀ aryl group, a heteroaryl group having 5 to 30 ring-forming atoms, a C₁-C₃₀ alkyloxy group, and a C₆-C₃₀ aryloxy group;
A₁ is selected from the group consisting of a C₆-C₃₀ arylene group and a heteroarylene group having 5 to 30 ring-forming atoms;
A₂ and A₃ are identical or different, and are each independently selected from the group consisting of a C₆-C₃₀ aryl group and a heteroaryl group having 5 to 30 ring-forming atoms;
the alkyl, alkenyl, alkynyl, cycloalkyl, heterocycloalkyl, aryl, heteroaryl, alkyloxy and aryloxy groups of R₃₁, R₃₂ and R₃₃, the arylene and heteroarylene groups of A₁, and the aryl and heteroaryl groups of A₂ and A₃ are each independently unsubstituted or substituted with one or more first substituents selected from the group consisting of a C₁-C₃₀ alkyl group, a C₂-C₃₀ alkenyl group, a C₂-C₃₀ alkynyl group, a C₆-C₃₀ aryl group, a heteroaryl group having 5 to 30 ring-forming atoms, a C₆-C₃₀ aryloxy group, a C₁-C₃₀ alkyloxy group, and a C₆-C₃₀ arylphosphine oxide group, wherein, when the first substituents are plural in number, they may be identical or different; and
the first substituents are each independently unsubstituted or substituted with one or more second substituents selected from the group consisting of a C₁-C₃₀ alkyl group, a C₂-C₃₀ alkenyl group, a C₂-C₃₀ alkynyl group, a C₆-C₃₀ aryl group, a heteroaryl group having 5 to 30 ring-forming atoms, a C₆-C₃₀ aryloxy group, a C₁-C₃₀ alkyloxy group, and a C₆-C₃₀ arylphosphine oxide group, wherein, when the second substituents are plural in number, they may be identical or different.

6. The organic light-emitting diode of claim 1, wherein the second electrode comprises a silver (Ag)-containing material.

7. The organic light-emitting diode of claim 1, wherein a thickness ratio between the diffusion barrier layer and the second electrode ranges from 1: 1.5 to 10.

8. The organic light-emitting diode of claim 6, wherein a maximum diffusion depth of an Ag⁺ ion, originating from the second electrode, in the organic layer is 20 nm or less.

9. The organic light-emitting diode of claim 1, wherein the diffusion barrier material has a lowest unoccupied molecular orbital (LUMO) energy level in a range of 2.0 to 3.5 eV.

10. An organic light-emitting display device comprising:
a substrate; and
a plurality of red organic light-emitting diodes, green organic light-emitting diodes, and blue organic light-emitting diodes disposed on the substrate;
wherein each of the plurality of red organic light-emitting diodes, green organic light-emitting diodes and blue organic light-emitting diodes comprises:
a first electrode disposed on the substrate;
a second electrode disposed opposite to the first electrode; and
an organic layer interposed between the first electrode and the second layer, and comprising a hole transport region, a light-emitting layer, an electron transport region, and a diffusion barrier layer,
wherein the diffusion barrier layer comprises one or more diffusion barrier materials selected from the group consisting of a 6- to 20-membered N-heterocyclic aromatic compound, a lithium complex, and a phosphine oxide-based compound.

11. The organic light-emitting display device of claim 10, wherein the 6- to 20-membered N-heterocyclic aromatic compound comprises a compound represented by Formula 1 below: 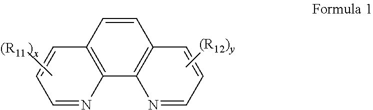
wherein:
R₁₁ and R₁₂ are identical or different, and are each independently selected from the group consisting of a C₁-C₃₀ alkyl group and a C₆-C₃₀ aryl group; and
x and y are each an integer in a range of 0 to 3.

12. The organic light-emitting display device of claim 10, wherein the lithium complex comprises a ligand containing a 6- to 20-membered N-heterocyclic ring.

13. The organic light-emitting display device of claim 12, wherein the lithium complex is represented by Formula 2 below: 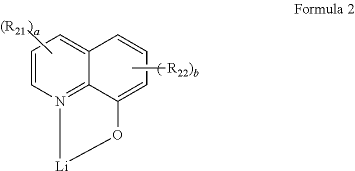
wherein:
R₂₁ and R₂₂ are identical or different, and are each independently selected from the group consisting of a C₁-C₃₀ alkyl group and a C₁-C₃₀ alkyloxy group; and
a and b are each an integer in a range of 0 to 3.

14. The organic light-emitting display device of claim 10, wherein the phosphine oxide-based compound is represented by Formula 3 or 4 below: 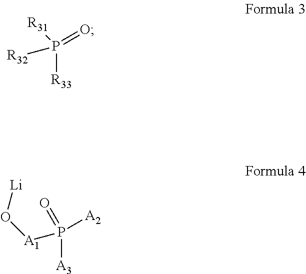
wherein:
R₃₁, R₃₂ and R₃₃ are identical or different, and are each independently selected from the group consisting of a C₁-C₃₀ alkyl group, a C₂-C₃₀ alkenyl group, a C₂-C₃₀ alkynyl group, a C₃-C₃₀ cycloalkyl group, a heterocycloalkyl group having 3 to 30 ring-forming atoms, a C₆-C₃₀ aryl group, a heteroaryl group having 5 to 30 ring-forming atoms, a C₁-C₃₀ alkyloxy group, and a C₆-C₃₀ aryloxy group;
A₁ is selected from the group consisting of a C₆-C₃₀ arylene group and a heteroarylene group having 5 to 30 ring-forming atoms;
A₂ and A₃ are identical or different, and are each independently selected from the group consisting of a C₆-C₃₀ aryl group and a heteroaryl group having 5 to 30 ring-forming atoms;
the alkyl, alkenyl, alkynyl, cycloalkyl, heterocycloalkyl, aryl, heteroaryl, alkyloxy and aryloxy groups of R₃₁, R₃₂ and R₃₃, the arylene and heteroarylene groups of A₁, and the aryl and heteroaryl groups of A₂ and A₃, are each independently unsubstituted or substituted with one or more first substituents selected from the group consisting of a C₁-C₃₀ alkyl group, a C₂-C₃₀ alkenyl group, a C₂-C₃₀ alkynyl group, a C₆-C₃₀ aryl group, a heteroaryl group having 5 to 30 ring-forming atoms, a C₆-C₃₀ aryloxy group, a C₁-C₃₀ alkyloxy group, and a C₆-C₃₀ arylphosphine oxide group, wherein, when the first substituents are plural in number, they may be identical or different;
the first substituents are each independently unsubstituted or substituted with one or more second substituents selected from the group consisting of a C₁-C₃₀ alkyl group, a C₂-C₃₀ alkenyl group, a C₂-C₃₀ alkynyl group, a C6-C₃₀ aryl group, a heteroaryl group having 5 to 30 ring-forming atoms, a C₆-C₃₀ aryloxy group, a C₁-C₃₀ alkyloxy group, and a C₆-C₃₀ arylphosphine oxide group, wherein, when the second substituents are plural in number, they may be identical or different.

15. The organic light-emitting display device of claim 10, wherein the second electrode comprises a silver (Ag)-containing material.

16. The organic light-emitting display device of claim 10, wherein a thickness ratio between the diffusion barrier layer and the second electrode ranges from 1: 1.5 to 10.

17. The organic light-emitting display device of claim 15, wherein a maximum diffusion depth of an Ag⁺ ion, originating from the second electrode, in the organic layer is 20 nm or less.

18. The organic light-emitting display device of claim 10, wherein the diffusion barrier material has a lowest unoccupied molecular orbital (LUMO) energy level in a range of 2.0 to 3.5 eV.

19. The organic light-emitting display device of claim 10, wherein:
the organic layer of the red organic light-emitting diode has a thickness in a range of 100 to 120 nm;
the organic layer of the green organic light-emitting diode has a thickness in a range of 80 to 100 nm, and
the organic layer of the blue organic light-emitting diode has a thickness in a range of 60 to 70 nm.

20. The organic light-emitting display device of claim 10, wherein:
the organic layer of the red organic light-emitting diode has a thickness in a range of 100 to 120 nm;
the organic layer of the green organic light-emitting diode has a thickness in a range of 80 to 100 nm; and
the organic layer of the blue organic light-emitting diode has a thickness in a range of 180 to 190 nm.
